(19) United States
(12) Patent Application Publication
(10) Pub. No.: US 2008/0047831 A1
(43) Pub. Date: Feb. 28, 2008

(54) Segmented/modular magnet bars for sputtering target

(76) Inventors: Hendryk Richert, Jena (DE); Roland Weidl, Bollberg (DE); Bernd Grunler, Zeulenroda (DE); Gerald Janicke, Bobbau (DE); Siegfried Kern, Braschwitz/Plossrnitz (DE); Uwe Kriltz, Jena (DE)

Correspondence Address: NIXON & VANDERHYE, PC, 901 NORTH GLEBE ROAD, 11TH FLOOR, ARLINGTON, VA, 22203, US

(21) Appl. No.: 11/509,075

(22) Filed: Aug. 24, 2006

(51) Int. Cl. C23C 14/00

(52) U.S. Cl. 204/298.12

(57) ABSTRACT

A modular and/or segmented magnetic bar for magnetron sputtering targets is provided. A magnet bar is made up of a plurality of magnet segments aligned in a substantially linear manner. One or more magnet bars may be provided. The positions of the magnet segments may be selectively adjusted to, for example, adjust magnetic field(s), replace magnet segment(s) that have been broken or damaged, and so forth.

### FIELD OF THE INVENTION

This invention relates to rotating sputtering targets, including the use of magnet bars therein, and/or methods of making the same. In certain example embodiments of this invention, a modular and/or segmented magnet bar for a sputtering target is provided, wherein a number of magnet elements may be arranged within a sputtering target to function as a single magnet bar structure. In certain example embodiments, the magnet segments may or may not be of equal lengths. In certain example embodiments, the segments may be tuned and/or replaced to, for example, adjust the magnetic field. Moreover, the segment(s) may also be replaced so as to repair segment(s) that have been broken, damaged, warped, etc.

### BACKGROUND AND SUMMARY OF EXAMPLE EMBODIMENTS OF THE INVENTION

The use of sputtering in order to deposit coatings on substrates is known in the art. For example, and without limitation, see U.S. Pat. Nos. 5,403,458; 5,317,006; 5,527,439; 5,591,314; 5,262,032; and 5,284,564. Briefly, sputter coating is an electric-discharge-type process which is conducted in a vacuum chamber in the presence of at least one gas. Typically, a sputtering apparatus includes a vacuum chamber, a power source, an anode, and one or more cathode targets which include material used to create a coating on an adjacent substrate (e.g., glass substrate or substrate of other material). The target may include an outer tube enclosing a magnet bar assembly including and an associated inner magnet bar support tube. More specifically, in certain known arrangements, the one or more magnet bars are secured to the underside of the support tube along substantially the entire length of the support tube. In certain example instances, the magnet bar may also include the support tube.

When an electrical potential is applied to the cathode target, the gas forms a plasma which bombards the target causing particles of the sputtering material from the target to leave the exterior surface of the target. These particles fall onto the substrate to form the coating thereon. The outer target tube typically rotates about the stationary magnets which are supported by the inner support tube so that particles are “sputtered” uniformly from the entire periphery of the target tube as it rotates past the fixed magnet bar(s).

FIG. 1 illustrates, in simplified form, a conventional magnetron sputtering apparatus 10. The apparatus includes metal walls 12 of the vacuum chamber in which sputtering is performed; a cylindrical rotating target/tube 14 that is supported at opposite ends by a bearing block 16 and a drive block 18 so that the target is rotatable about axis 20; and an inner stationary magnet bar support tube 22 that supports a magnet carrier and an associated magnet (represented by block 24) that extends along the underside of the inner support tube 22, substantially the entire length of both the inner support tube and the outer target tube. Gas is supplied to the vacuum tube via an external gas supply 26 while power is supplied via external power supply 28. The chamber is evacuated by a vacuum pump 30.

In a typical sputtering process, the plasma formed when an electrical potential is applied to the cathode target bombards the target and the dislodged particles of sputtering material from the target fall onto the substrate 32 to be coated, forming a coating thereon. Throughout the process, the target tube may be cooled to a specified temperature; e.g., cooling water from a source 34 may be introduced into the interior of the hollow inner support tube 22 at one end thereof through the bearing block 16, and may exit the opposite end of the tube through a plurality of nozzle or jet apertures provided in an end plate. The apertures may be arranged to emit streams parallel to the longitudinal axis of the target tube and/or at an acute angle thereto. The cooling water then reverses direction and flows back along the exterior of the inner tube 22, in the chamber or space 40 radially between the inner support tube 22 and the outer rotating target tube 14, exiting the target tube via the same bearing block 16. Note that while the support tube 22 is terminated short of the drive block 18 to permit the cooling fluid to exit the tube and reverse flow through the chamber 40, an inner spindle 42 that may be fixed to the end plate, supports the inner tube in the drive block 18.

Conventional sputtering targets include a magnetic shim (e.g. an electrical shunt). Shunts can be adjusted by tightening or loosening one or more screws that may run the length of the shunt. Shunts also may be adjusted by adding and/or removing shims to change the height. Adjusting the physical height of the shunt may cause a corresponding adjustment to the magnet field created by the sputtering target. This adjustment process is sometimes referred to as “tuning.” However, long magnetic bars extending the length of the target may be bent when they are tuned, thus resulting in non-uniform distances with respect to their carrier tubes. Fine-tuning often is difficult because a large, typically rigid element is being adjusted. This process also may reduce the lifetime of a long magnet bar which extends the length of the target, which may need to be replaced in its entirety if even part of it becomes damaged. Moreover, when the magnet carrier is not separated from (or evenly separated from) the mounting, tuning might produce “bending effects.” These phenomena may result in non-uniform magnetic fields being produced, thus leading to non-uniform sputtering. Also, tuning conventional extremely long magnet bars (which extend the length of the target) tends to be comparatively less precise, further altering the magnetic field produced in potentially unpredictable and/or undesirable ways.

Thus, it will be appreciated that there exists a need in the art for a sputtering target and/or a method of making the same to overcome one or more of these and/or other disadvantages.

Certain example embodiments of this invention provide a sputtering target with a segmented magnet bar assembly. Such example embodiments may comprise a rotatable sputtering tube, with sputtering target material on an outer surface thereof, the sputtering tube housing a modular stationary magnet bar structure therein, and each magnet bar of the structure may include at least two elongated magnet segments arranged in series with one another substantially along the length of the target.

In certain example embodiments, a modular magnet bar may comprise from about 3-25, more preferably from about 3-10, different magnet segments in series with one another (arranged in a co-linear manner), with an example number being about five magnet segments for a particular magnet bar. In certain example embodiments, two or more of the magnet segments of a given bar may be of approximately equal size.

In certain example embodiments of this invention, there is provided a rotatable magnetron sputtering target comprising: a rotatable target tube comprising sputtering material on an outer surface thereof to be sputter deposited on a substrate, a magnet bar structure provided within the rotatable target tube, wherein the magnet bar structure is stationary when the rotatable tube is rotating during sputtering, and wherein the magnet bar structure comprises at least one elongated magnet bar which includes a plurality of different magnet segments that are aligned in a substantially linear manner along at least a substantial portion of the magnet bar structure.

In certain example embodiments of this invention, one or more of the magnet segments' height(s) may be adjusted to adjust a magnetic field produced during sputtering. One or more of the magnet segments can be replaced with other magnet segments to vary the modular magnetic bar in certain example embodiments (or the same or different type). Different magnetic fields may be produced based at least in part on the type of magnet segments making up a given magnet bar. Thus, it will be appreciated that the segmented magnet bars of certain example embodiments of this invention are advantageous in that they provide for easier and more efficient magnetic field adjustments, and easier and more cost effective replacement of damaged magnet bar portions.

Certain example embodiments provide a sputtering target, comprising a rotatable tube housing a modular magnet bar therein, a given magnet bar including at least two magnet segments that are approximately linearly arranged with each other; and a target material layer provided on the outer surface of the rotatable tube. Each of the magnet segments may be located on a magnetic carrier, and the magnet carrier may capable of being adjustably attached to a main mounting part. In certain example embodiments of this invention, screw(s) may be adjusted to change a corresponding magnet segment's height and/or position (a change in a magnetic segment's height and/or position can result in a change in a magnetic field produced during sputtering) thereby permitting one to adjust the sputtering features of a given target in a desirable manner.

In certain example embodiments, a modular magnet bar for use in a sputtering target is provided. The modular magnetic bar may comprise at least two magnetic segments, with each magnetic segment being located on a magnet carrier or magnet carrier module, and each magnet carrier may be operable to have its height/position adjusted.

In certain example embodiments, each magnetic carrier's height or other position may be adjusted by tightening and/or loosening at least one screw or other adjustable member. In certain other example embodiments, each magnetic carrier's height or other position may be fixed and/or adjusted by tightening and/or loosening a screw(s) or other type of adjustable device and/or fastener.

### BRIEF DESCRIPTION OF THE DRAWINGS

These and other features and advantages will be better and more completely understood by reference to the following detailed description of exemplary illustrative embodiments in conjunction with the drawings, of which:

FIG. 1 is a simplified and partially schematic side elevation of a conventional sputtering apparatus;

FIG. 2 shows a side cross-section of a modular magnet bar structure in accordance with an example embodiment of this invention;

FIG. 3 is a partial perspective view of the modular magnetic bar structure of FIG. 2 showing a central portion of the stationary magnet bar structure which is located inside of the rotating sputtering target tube;

FIG. 4 is a partial perspective view of an end portion of the modular magnetic bar structure of FIGS. 2-3; and

FIG. 5 is a perspective view of a significant portion of the modular magnet bar structure of FIGS. 2-4.

### DETAILED DESCRIPTION OF EXAMPLE EMBODIMENTS OF THE INVENTION

Referring now more particularly to the accompanying drawings in which like reference numerals indicate like parts throughout the several views.

Certain example embodiments provide a modular and/or segmented magnetic bar structure for sputtering targets. The structure may include a plurality of elongated magnet bars, each magnet bar including a plurality of segments aligned linearly or in series. Such modular magnetic bars may, for example, include five segments (although any suitable number of segments may be provided per bar). Considerations taken into account as to how may segments to provide per magnet bar may include, for example, the size of the sputtering target, the degree of accuracy required with respect to the magnetic field, etc. Multiple segments may be arranged within a sputtering target to function as a single magnet bar. In general, though, more segments in the modular design will allow for more finely-tuned magnetic fields, as each segment preferably can be individually adjusted in certain example non-limiting embodiments of this invention.

Each segment of a given magnet bar may be sized the same or substantially the same in certain example embodiments; however, the invention is not so limited. Indeed, multiple different segments may be substituted in certain example embodiments to customize the magnetic field to be generated. For example, changing an end module with a different magnet row length may increase or decrease the target exploitation. Thus, providing a number of magnetic segments in accordance with pre-determined configurations may produce a known or desired magnetic field for use in the sputtering operation. This process may save time in maintenance and setup of sputtering targets. Manufacturing efficiency and manufacturing flexibility thus may also be improved. The modular design may also minimize or reduce bending of magnetic bars. The smaller magnetic segments (smaller than the overall bar length) also may have higher flexibilities, when compared with a single magnetic bar that runs the entire length of the sputtering target. The minimization or reduction in bowing, warping, and/or sagging of the modular or magnetic elements, in turn, leads to increased uniformity of the magnetic field and thus of sputtering. In certain example embodiments of this invention, separating of the magnet carrier from the mounting may be used to reduces bending effects when the heights of the magnets are adjusted (e.g., when tuning the elements). Thus, the overall magnetic homogeneity and uniformity of the field may be increased.

Also, as will be described in further detail below, allowing the mounting device and magnet carrier device to be easily disconnected advantageously allows the adjustment of the magnets to reduce bending of the whole system. Also reduced may be mechanical impacts on the carrier related to adjustments and/or tuning, which would decrease the predictability of the system. In an example embodiment, moreover, stability may be increased, and the bending related to the mass and gravitation may be reduced by pre-bending the system to the opponent side and fixing it in such a way as to reduce bending during operation.

An example material which may be used in the tube (other than the magnets themselves) is a nonmagnetic stainless steel.

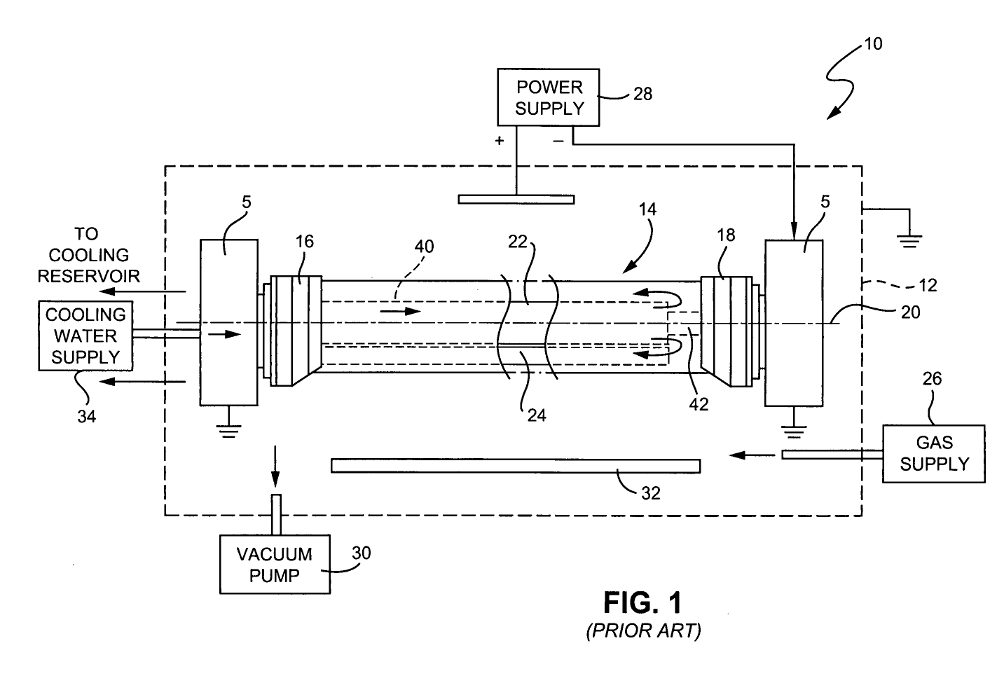

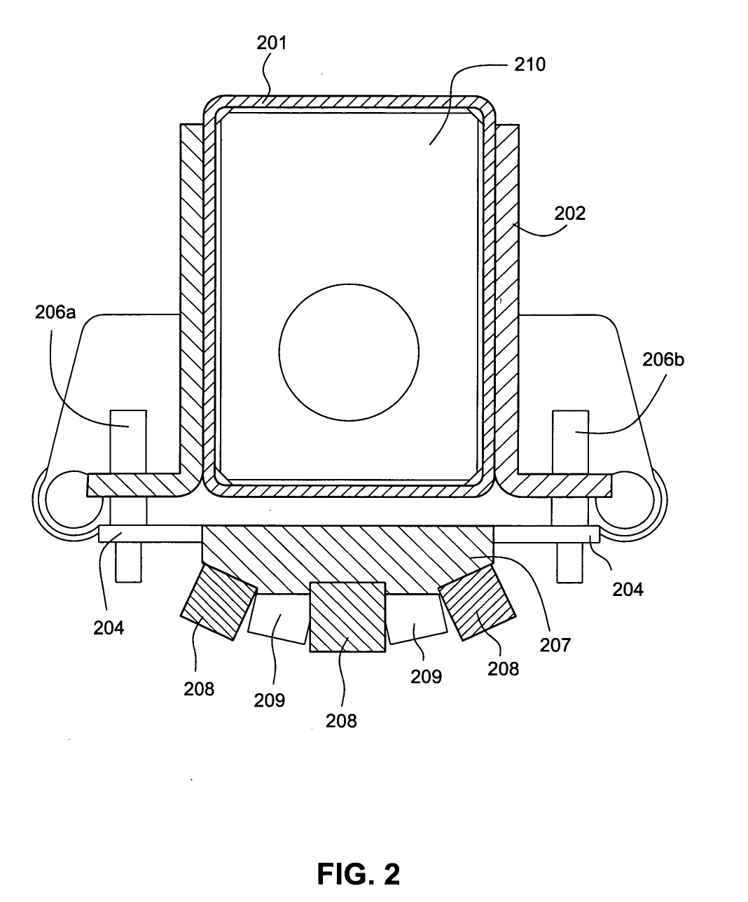

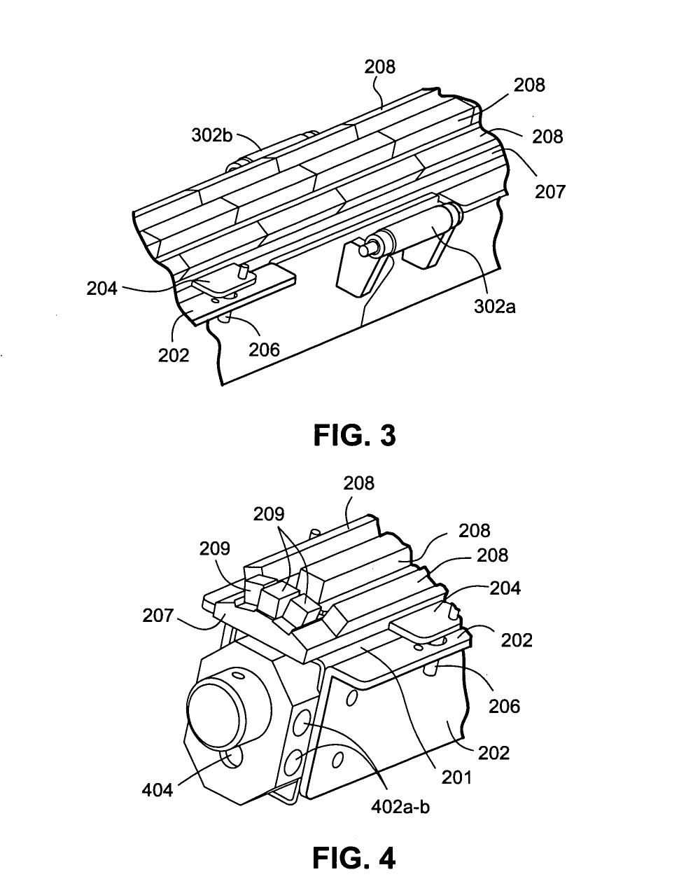

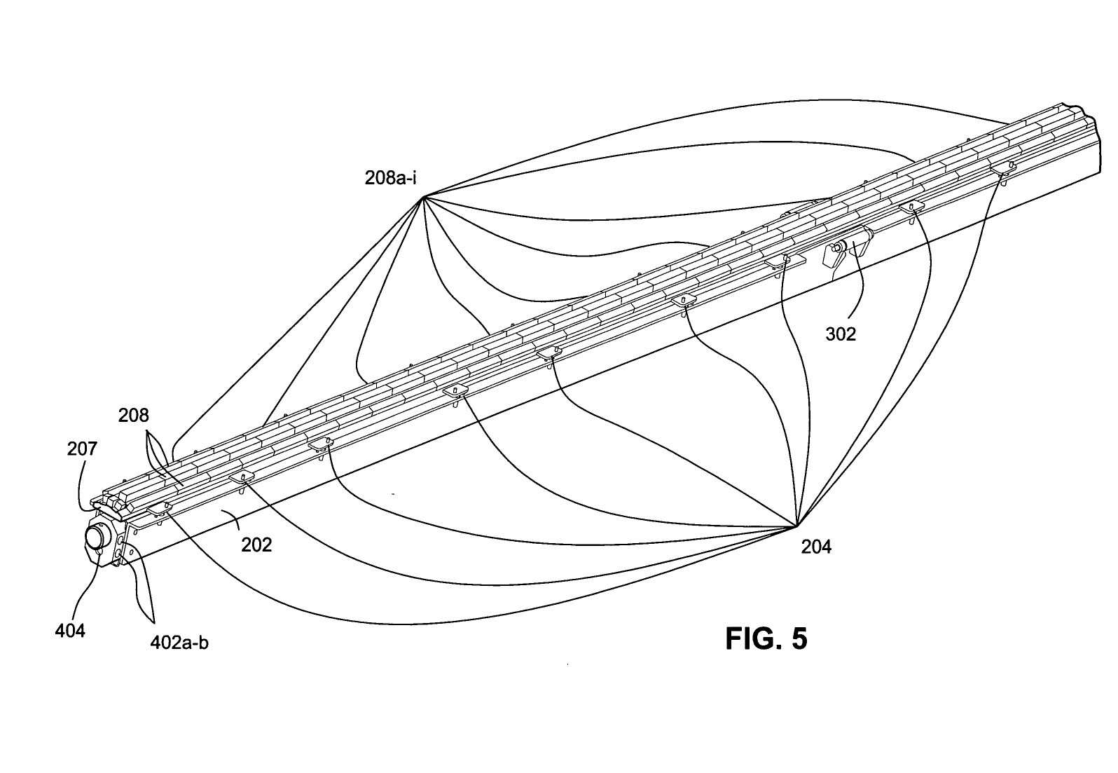

FIG. 2 shows a cross-section of a modular magnetic bar structure in accordance with an example embodiment of this invention. Meanwhile, FIG. 3 is a partial perspective view of the modular magnetic bar structure of FIG. 2 showing a central portion of the stationary magnet bar structure which is located inside of the rotating sputtering target tube; FIG. 4 is a partial perspective view of an end portion of the modular magnetic bar structure of FIGS. 2-3; and FIG. 5 is a perspective view of a significant portion of the modular magnet bar structure of FIGS. 2-4. The magnet bar structure of FIGS. 2-5 may be used in connection with a rotating magnetron sputtering apparatus as shown in FIG. 1, where the sputtering tube/target with the sputtering material thereon rotates around the stationary magnet structure.

Referring to FIGS. 2-5, elongated main mounting part (static profile or support) 202 is mounted on elongated hollow tube 201 and is connected to a magnet carrier support 204 and a magnet carrier or magnet carrier module 207. The hollow portion of tube 201 is indicated at 210. Mounting part 202 may be made up of one or multiple parts in different embodiments of this invention, but may include two spaced apart members as shown in FIG. 2 that are provided on opposite sides of tube 201. Magnet carrier 207 is elongated in shape in supports one or more elongated magnet segments 208. Each magnet bar is made up of a plurality of elongated magnet segments 208 arranged in a substantially linear manner, or in series (e.g., see FIGS. 2, 3 and 5). In other words, a magnet bar may be said to be a row of substantially aligned magnet portions. Immediately adjacent ones of the linearly arranged magnet segments 208 of a given magnet bar may be spaced apart from one another, or alternatively may abut one another, in different example embodiments of this invention. It can be seen in FIGS. 2-5 that three different magnet bars (each magnet bar being made up of a plurality of magnet segments 208 arranged in a substantially linear manner) are provided for this particular embodiment, although one, two, four or more magnet bars may be provided in alternative embodiments of this invention. In other words, while there are three substantially parallel magnet rows 208 shown in FIGS. 2-5, the assembly may instead have only two substantially parallel magnet rows, or alternatively may have four, five, etc. substantially parallel magnet rows in certain example instances. In addition to supporting the adjustable magnet segment(s) 208 of the respective magnet bars, the magnet carrier 207 also may optionally support end magnets 209 as shown in FIGS. 2 and 4. End magnets 209 are located at one or both ends of the carrier 207 as shown in FIGS. 4-5, and thus at one or both ends of the bars which are made up of the magnet segments 208. In certain example embodiments of this invention, a plurality of magnet carrier supports 204 are provided in series on each side of the carrier 207 along the length of the target, with one or more magnet segments 208 being mounted for adjustment via each carrier support 204. Generally, the mounting part 202 extends in a continuous manner along substantially the entire length of each side of tube 201. One or more magnet carriers 207 may be provided along the length of the tube 201 so as to be aligned in series, which each carrier 207 optionally being selectively adjustable with respect to position thereby permitting the position of the magnet segment(s) 208 mounted thereon to be selectively adjusted along with that of 207. In certain example instances, the magnet bar portion of the system may also include the support tube.

Thus, it will be appreciated that there may be provided a rotatable magnetron sputtering target comprising a rotatable target tube (see 14 in FIG. 1) comprising sputtering material on an outer surface thereof to be sputter deposited on a substrate (e.g., onto a glass substrate or the like), a magnet bar structure provided within the rotatable target tube 14, wherein the magnet bar structure is stationary when the rotatable tube 14 is rotating during sputtering, and wherein the magnet bar structure comprises at least one elongated magnet bar which includes a plurality of different magnet segments 208 that are aligned in a substantially linear manner along at least a substantial portion of the magnet bar structure. The magnet segments 208 are independently adjustable in certain example embodiments, relative to one or more other magnet segments of the bar; and in certain example embodiments the modules may be linked in order to prevent or reduce a gap between adjacent magnets which could create plasma issues.

In certain example embodiments, the connection between mounting part 202 and magnet carrier support 204 is made using screws 206a-b. However, it will be appreciated that other methods or techniques of attaching mounting part 202 to magnet carrier support 204 may instead be used. It also will be appreciated that mounting part 202 and magnet carrier support 204 may be fixedly attached to each other, though this arrangement is less preferable because, for example, it potentially limits the degree to which the magnetic elements 208 can be tuned/adjusted. The advantages of tuning using the techniques disclosed herein are further described below.

According to an example embodiment of this invention, turning one of screws 206a-b adjusts the distance between the corresponding magnet segment 208 which is located closest to the screw and tube 201; and optionally turning the other screw which is also located adjacent the segment 208 but across the tube 201 may fix the adjustment. In such an example embodiment, it will be appreciated that the handedness may be reversed—e.g., screw 206a may be used for adjusting the height and screw 206b may be used for fixing the height, or vice versa. It also will be appreciated that more than two screws may be used to fix each magnetic carrier support 204 to mounting part 202. By adjusting the position of magnet carrier support 204 relative to mounting part 202 using one of the screws, the height/position of magnet bar segment(s) 208 mounted on that particular support 204 will also be adjusted in a desirable manner thereby permitting one to easily adjust the positions of magnet segments and thus adjust the magnetic field to be used during sputtering. Using such an arrangement, the magnetic field may be adjusted for substantial uniformity with a very fine accuracy. For purposes of example and without limitation, one turn of a screw (206a or 206b) in certain example embodiments may translate into about a 0.8 mm adjustment in height of the closest corresponding magnet segment 208. It will be appreciated that in other example embodiments, both of screws 206a-b may be used for height adjustment and/or for fixing the height.

FIG. 3 illustrates part of the structure of FIGS. 2 and 4-5, in a partial perspective view. Rollers 302a-b may be mounted, directly or indirectly, on mounting part or support 202 and are adapted to come into rotating contact with the inner wall of the rotating outer tube 14 which supports the target material to be sputtered. Thus, the rollers 302a-b prevent the inner rotating wall of the target tube (see rotating target tube 14 in FIG. 1 which rotates about axis 20) from contacting or damaging the mounting part 202, tube 201, and magnets 208-209. In other words, rollers 302a-b may be located in such a way as to prevent or reduce damage to the magnetic elements 208-209 and/or the rotating outer tube 14 in case the magnetic elements become too close to the walls of the rotating outer tube 14 as a result of shimming and/or adjustments via screws 206a-b. It will be appreciated that the position of the rollers may also help avoid and/or reduce other potential mechanical influences.

Water may be fed through the magnet bar structure from one side via an inlet and out through the other side via an outlet, for cooling purposes. FIG. 4 illustrates holes for water inlet and/or outlet in accordance with an example embodiment. The assembly includes several side inlet/outlet holes 402a-b as well as a front inlet/outlet hole 404 for water distribution, for purposes of cooling the structure during sputtering operations. This arrangement enables the water or other coolant flow to be varied and more precisely defined, as optional steel components (not shown) may be attached to the holes to vary the sizes thereof, independently and adjustably. In certain example embodiments the inlet/outlet segments may be screwed or other wise attached to the magnetic segments, potentially providing more opportunities for modifications and/or fine adjustments.

FIG. 5 illustrates an elongated portion of the magnet bar structure of FIGS. 2-4 (or course, the rotating target tube which rotates around the stationary magnet bar structure is not shown in FIGS. 2-5 for purposes of simplicity). It will be appreciated that magnetic segments 208 are attached to magnet carrier supports and corresponding magnet carrier modules 207. Attaching magnet segments 208 to magnetic carrier modules in this way allows the height of the magnetic segments 208 to be adjusted, as noted above, thus increasing and/or decreasing the magnetic field and sputter rate as desired. One conventional magnet bar tuning method involved the addition of small plates (shims) under a magnet bar extending the length of the target. However, this arrangement did not allow for good, long range uniform tuning of the magnetic field, which is now possible with certain example embodiments of this invention. Thus, in certain example non-limiting embodiments of this invention, such shims are not needed. As noted above, in certain example embodiments of this invention a technique for tuning magnet segment 208 positions involves adjustment of one or more screws of the like. Additionally, in certain example embodiments, a shortened magnet carrier module length may allow for yet more fine adjustment to the magnetic field. This modular system may allow magnet segments to be easily replaced. For example, magnet segments 208 and/or carrier modules 207 may be selectively replaced based on, for example, whether they are defective, damaged, warped, bent, broken, etc. Individual magnet segments may be replaced without replacing the entire magnet bar which is made up of a plurality of magnet segments 208 aligned in a linear manner. This may allow for easier installation and/or maintenance, while reducing replacement times and costs.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A rotatable magnetron sputtering target comprising:
a rotatable target tube comprising sputtering material on an outer surface thereof to be sputter deposited on a substrate,
a magnet bar structure provided within the rotatable target tube, wherein the magnet bar structure is stationary when the rotatable tube is rotating during sputtering, and
wherein the magnet bar structure comprises at least one elongated magnet bar which includes a plurality of different magnet segments that are aligned in a substantially linear manner along at least a substantial portion of the magnet bar structure.

2. The sputtering target of claim 1, wherein the magnet bar comprises at least five magnet segments aligned in a substantially linear manner, each of the magnet segments being elongated in shape.

3. The sputtering target of claim 1, wherein two or more of the magnet segments of the magnet bar are substantially equal in size.

4. The sputtering target of claim 1, wherein the magnet bar structure comprises at least two substantially parallel magnet bars.

5. The sputtering target of claim 1, wherein the magnet bar structure comprises at least three substantially parallel magnet bars.

6. The sputtering target of claim 1, wherein the magnet bar structure comprises at least one roller located on a lateral side thereof for rotating engagement with an inner periphery of the rotatable target tube.

7. The sputtering target of claim 1, further comprising means for adjusting the position of one or more of the magnet segments.

8. The sputtering target of claim 1, further comprising at least one screw for adjusting a height of one or more of the magnet segments so that a magnet field caused by the one or more magnet segments can be adjusted.

9. The sputtering target of claim 1, one of more of the magnet segments is supported by a magnet carrier which in turn is operatively associated with a magnet carrier support, and wherein a position of the magnet carrier support is adjustable relative to a tubular support member so as to cause the position of the magnet carrier and at least one of the magnet segments to be adjusted.

10. The sputtering target of claim 1, wherein at least three substantially parallel magnet segments of three respective magnet bars are all supported by a magnet carrier.

11. The sputtering target of claim 1, wherein a plurality of magnet segments of the magnet bar are independently adjustable.

12. A sputtering target comprising:
a rotatable target tube comprising sputtering material on an outer surface thereof,
a magnet bar structure provided within the rotatable target tube, and
wherein the magnet bar structure comprises at least one elongated magnet bar which includes a plurality of separate independently adjustable magnet segments that are aligned in a substantially linear manner.

13. The sputtering target of claim 12, wherein immediately adjacent ones of the substantially linearly arranged magnet segments of the magnet bar are spaced apart from each other.

14. The sputtering target of claim 12, wherein immediately adjacent ones of the substantially linearly arranged magnet segments of the magnet bar abut one another.

15. The sputtering target of claim 12, wherein the magnet bar comprises at least five magnet segments aligned in a substantially linear manner, each of the magnet segments being elongated in shape.

16. The sputtering target of claim 12, wherein two or more of the magnet segments of the magnet bar are substantially equal in size.

17. The sputtering target of claim 12, wherein the magnet bar structure comprises at least two substantially parallel magnet bars.

18. The sputtering target of claim 12, further comprising means for adjusting the position of one or more of the magnet segments relative to at least certain other magnet segments of the magnet bar.

19. The sputtering target of claim 12, further comprising at least one screw for adjusting a height of one or more of the magnet segments so that a magnet field caused by the one or more magnet segments can be adjusted.
